(19) United States
(12) Patent Application Publication
(10) Pub. No.: US 2026/0282813 A1
(43) Pub. Date: Sep. 17, 2026

(54) HANDLING PANEL SUBSTRATES

(71) Applicant: Applied Materials, Inc., Santa Clara, CA (US)

(72) Inventors: Alejandro Lizarraga MALDONADO, Santa Clara, CA (US); Harish PENMETHSA, Santa Clara, CA (US); Vasu R. CHINTALA, Santa Clara, CA (US); Manohar KORLAPATI, Santa Clara, CA (US)

(21) Appl. No.: 19/471,403

(22) PCT Filed: Aug. 6, 2024
(86) PCT No.: PCT/US2024/041021

§ 371 Date: Oct. 1, 2025

Related U.S. Application Data
(60) Provisional application No. 63/540,040, filed on Sep. 22, 2023.

(51) Int. Cl. H10P 72/00; H10P 72/30; H10P 72/50

(52) U.S. Cl. CPC H10P 72/0606; H10P 72/3302; H10P 72/3306; H10P 72/53

(57) ABSTRACT

Apparatuses and methods for processing substrates are provided herein. In some embodiments disclosed herein, a processing system includes a processing chamber comprising one or more of a rotating base for receiving a panel substrate, wherein the rotating base is capable of adjusting an orientation of the panel substrate, and a set of sensors, a transportation mechanism capable of transporting the panel substrate into or out of the processing chamber or adjusting a translational position of the panel substrate, and a computing device capable of receiving sensor data from the set of sensors and computing, based on the sensor data, a rotational correction to adjust an orientation of the panel substrate to be performed by the rotating base or a translational correction to adjust a translational position of the panel substrate to be performed by the transportation mechanism.

### BACKGROUND

### Field

Embodiments of the present disclosure generally relate to apparatus and methods of processing substrates in an electronic device fabrication system, and more particularly, to apparatus and methods for handling panel substrates.

### Description of the Related Art

Substrate processing in electronic device fabrication often involves performing a deposition process on a side of a substrate. However, process chambers are typically designed for handling wafers (e.g., disk-shaped substrates). There is a particular challenge when processing some substantially rectangular substrates, such as panels. For example, unlike wafers, an orientation of a panel during processing is critical (e.g., to ensure even deposition on the panel). Even slight deviations from a desired orientation can negatively impact the deposition result, causing severe drop in panel throughput.

There have been attempts to change the position and orientation of panel substrates in the processing chamber. However, such methods often rely on a single transportation mechanism (e.g., a robot arm) to perform multiple iterative corrections of the panel position and orientation, which can be very time consuming. Furthermore, they may not rely on sensors specifically designed to detect a position and an orientation of the panel, resulting in inefficiencies during processing.

Accordingly, there is a need in the art for apparatuses and methods for handling panel substrates.

### SUMMARY

Embodiments described herein generally relate to physical vapor deposition (PVD) deposition of substrates in an electronic device fabrication process. More particularly, embodiments described herein provide apparatuses and methods for handling panel substrates.

In one embodiment, a processing system includes a processing chamber comprising one or more of a rotating base for receiving a panel substrate, wherein the rotating base is capable of adjusting an orientation of the panel substrate, and a set of sensors, a transportation mechanism capable of transporting the panel substrate into or out of the processing chamber or adjusting a translational position of the panel substrate, and a computing device capable of receiving sensor data from the set of sensors and computing, based on the sensor data, a rotational correction to adjust an orientation of the panel substrate to be performed by the rotating base or a translational correction to adjust a translational position of the panel substrate to be performed by the transportation mechanism.

In another embodiment, a method comprises receiving sensor data from a set of sensors indicative of a panel substrate, computing, based on the sensor data, a position and an orientation of the panel substrate, computing, a rotational correction to adjust an orientation of the panel substrate to be performed by a rotating base or a translational correction to adjust a translational position of the panel substrate to be performed by a transportation mechanism, and commanding the rotating base to perform the rotational correction or the transportation mechanism to perform the translational correction.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only example embodiments and are therefore not to be considered limiting of its scope, and may admit to other equally effective embodiments.

FIG. 1A depicts an example substrate processing system for handling panel substrates, according to certain embodiments.

FIG. 1B is a schematic top isometric view of a portion of the substrate processing system of FIG. 1A including a flipper module, according to certain embodiments.

FIG. 1C is a schematic top isometric view of a portion of the substrate processing system of FIG. 1A including a flipper module, according to certain embodiments.

FIG. 1D depicts an example of the transfer portions of the substrate processing system for handling panel substrates, according to certain embodiments.

FIGS. 2A-B depict an example sensor array for handling panel substrates, according to certain embodiments.

FIGS. 3A-B depict an example scenario for correction calculation for handling panel substrates, according to certain embodiments.

FIG. 4 is a flow diagram of example operations for handling panel substrates, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to an electronic device fabrication systems that are configured to perform one or more processes on panel substrates. Some embodiments disclosed herein relate to physical vapor deposition (PVD) processes performed on panel substrates in an electronic device fabrication system. More particularly, embodiments described herein provide apparatuses and methods for handling panel substrates.

Embodiments described herein enable moving a panel substrate into a target position and a target orientation using a transportation mechanism and a rotational base, respectively, in contrast to conventional approaches in which the positions and orientations of panel substrates are adjusted using just one mechanism, such as a robot arm. Correcting the position and orientation of a panel substrate using separate mechanisms allow fast and accurate corrections, increasing throughput.

Embodiments described herein incorporate sensors designed specifically for detecting a position of a panel substrate though its corners. Recognizing corners of a panel substrate allows fast recognition of the position and orientation of the panel substrate, which further allows accurate calculations of a translational correction and/or a rotational correction needed to move the panel substrate into a target position and a target orientation to ensure successful processing.

### Example Substrate Processing System

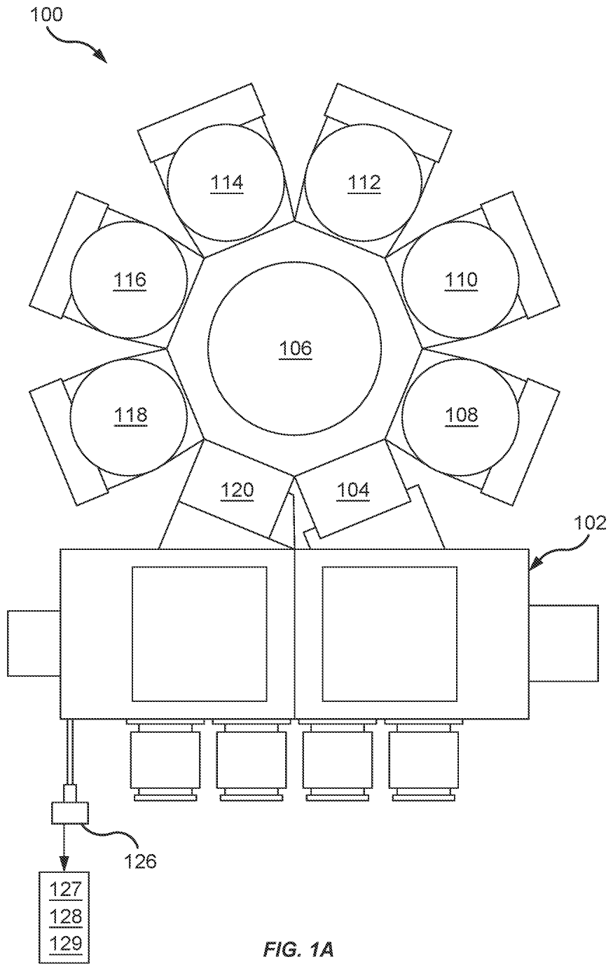

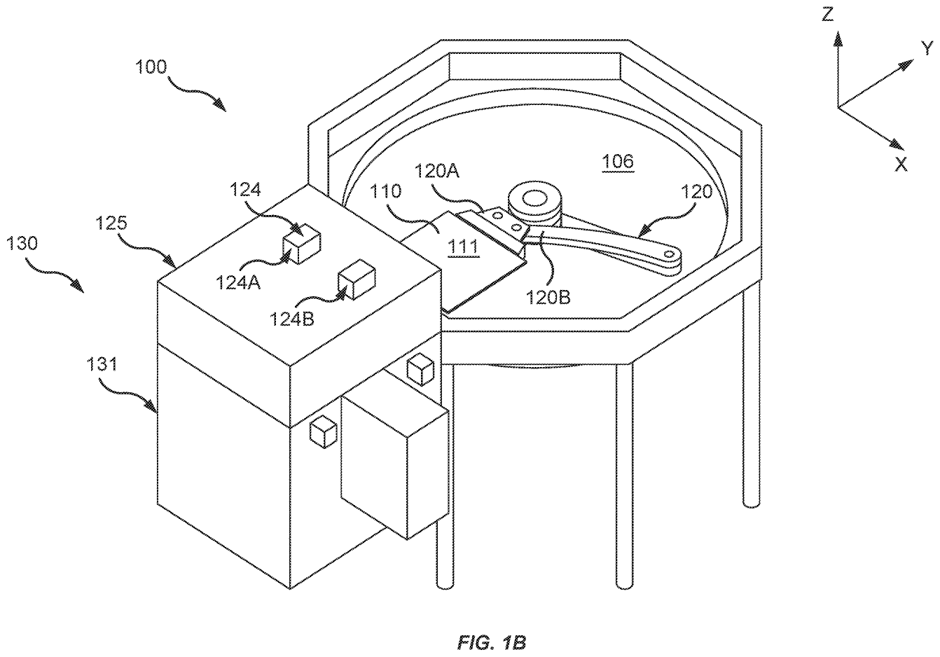

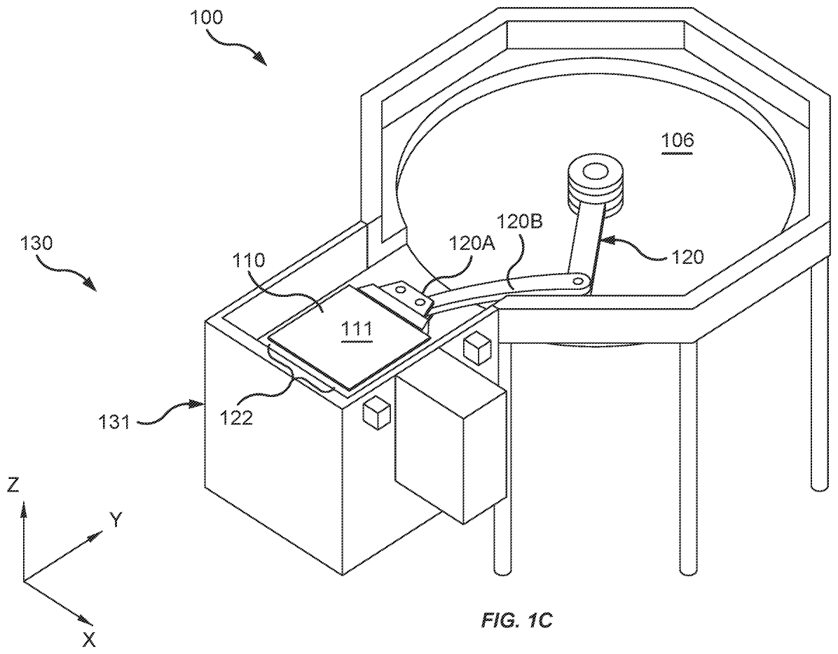

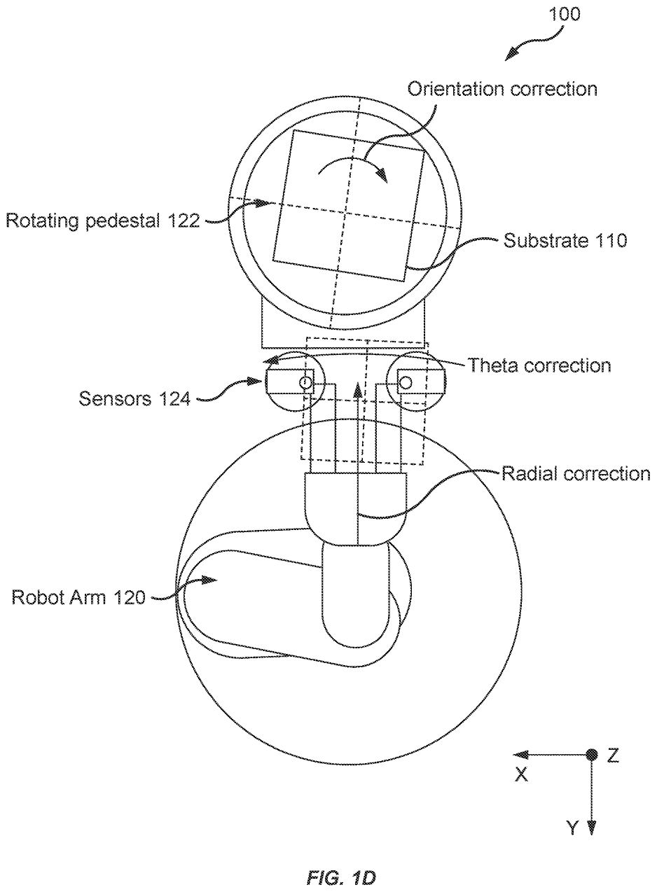

FIG. 1A illustrates an example substrate processing system 100, according to certain embodiments. FIGS. 1B-1D illustrate examples of portions of the substrate processing system 100, according to certain embodiments. In certain embodiments, the substrate processing system 100 is particularly configured for processing substantially rectangular or square substrates, such as panel 110. As used herein, the term “panel” generally refers to a substantially rectangular substrate, which may be a largely rectangular or square substrate that includes some small notches on one or more sides. A panel can be used in the formation of device packages or large panel displays. In some device packaging examples, a panel may include a large surface area substrate that includes a polymer material disposed over a structural core.

Substrate processing system 100 can include transportation mechanism 120 (or transfer robot 120), substrate support base 122 (also known as rotating pedestal 122 or base 122), and sensor array 124 that is disposed over the base 122. In some examples, transportation mechanism 120 is located in a transfer chamber 106, whereas base 122 and sensor array 124 are located in a processing chamber 130 (FIGS. 1B-1C) coupled to the transfer chamber 106. The sensor array 124 will include one or more sensors, such as sensors 124A and 124B shown in FIG. 1B. A process chamber 130 can be positioned in one or more of the processing chamber positions 108, 110, 112, 114, 116 and 118 in the substrate processing system 100, as shown in FIG. 1A. In general, the process chamber 130 can include an atomic layer deposition (ALD) chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, or cool down), or other type of substrate processing chamber. In some embodiments, the process chamber 130 includes a PVD deposition chamber that is adapted to deposit a film by a “sputtering” process on one or more sides 111 of a panel 110.

FIG. 1A is a schematic top view of an exemplary substrate processing system 100 (also referred to as a “processing platform”), according to certain embodiments. In certain embodiments, the substrate processing system 100 is particularly configured for processing large-area substrates. As used herein, the term “panel” may refer to a large-area substrate that can be used in the formation of device packages or large panel displays. In some device packaging examples, a “panel” may include a large surface area substrate that includes a polymer material disposed over structural core. The substrate processing system 100 generally includes an equipment front-end module (EFEM) 102 for loading substrates into the processing system 100, a first load lock chamber 104 coupled to the EFEM 102, a transfer chamber 106 coupled to the first load lock chamber 104, and a plurality of other chambers coupled to the transfer chamber 106 as described in detail below. The transfer chamber 106 can include a transportation mechanism, such as transportation mechanism 120 as depicted in FIGS. 1A-1D.

Proceeding counterclockwise around the transfer chamber 106 from the first load lock chamber 104, the processing system 100 includes a first dedicated degas chamber 108, a first pre-clean chamber 110, a first deposition chamber 112, a second pre-clean chamber 114, a second deposition chamber 116, a second dedicated degas chamber 118, and a second load lock chamber 105. The chambers 110, 112, 114, and 116 can each include a rotational base and sensor array, such as base 122 and sensor array 124 as depicted in FIGS. 1A-1D.

In certain embodiments, the transfer chamber 106 and each chamber coupled to the transfer chamber 106 are at vacuum. As used herein, the term “vacuum” may refer to pressures below about 10⁻² Pa. However, some high-vacuum systems may operate below 10⁻⁷ Pa. In certain embodiments, the vacuum is created using a turbomolecular pump coupled to the load lock chambers 104, 105. However, other types of vacuum pumps are also contemplated.

In certain embodiments a system controller 126, also referred to herein as a processing chamber controller, includes a central processing unit (CPU) 127, a memory 128, and support circuits 129. The system controller 126 is used to control a process sequence when processing the panel 110, including the substrate transferring and substrate position and orientation correction methods as described above. The CPU 127 is a general-purpose computer processor configured for use in an industrial setting for controlling the processing system 100 and sub-processors related thereto. The memory 128 described herein, which is generally non-volatile memory, may include random access memory, read-only memory, floppy or hard disk drive, or other suitable forms of digital storage, local or remote. The support circuits 129 are conventionally coupled to the CPU 127 and may comprise cache, clock circuits, input/output subsystems, power supplies, and the like, and combinations thereof. Software instructions (i.e., software program) and data can be coded and stored within the memory 128 for instructing a processor within the CPU 127. A software program readable by CPU 127 in the system controller 126 determines which tasks are performable by the components in the processing system 100. Typically, the software program, which is readable by CPU 127 in the system controller 126, includes code, which, when executed by the processor (CPU 127), performs tasks relating to the processing and substrate transfer schemes described above. The software program may include instructions that are used to control the various hardware and electrical components within the processing system 100 so that the methods described herein can be performed. In some embodiments, the program includes instructions that are used to perform one or more of the methods of correcting the position and orientation of a substrate as described above. For example, CPU 127, a memory 128, and support circuits 129 can be communicatively coupled with the transportation mechanism, the rotational base and sensor arrays to correct the position and orientation of a substrate in a chamber, as discussed above.

In certain embodiments, substrates are loaded into the processing system 100 through a door (also referred to as a “slit valve”), in the first load lock chamber 104 and unloaded from the processing system 100 through a door in the second load lock chamber 105. In certain embodiments, a stack of substrates is supported in a cassette, which is placed in the first load lock chamber 104. Once the first load lock chamber 104 is pumped down, one substrate at a time is retrieved from the cassette using a robot located in the transfer chamber 106. In some embodiments, the second load lock chamber 105 receives a single substrate after processing has been performed on each side and unloads the processed substrate to the EFEM 102. However, other loading and unloading configurations are also contemplated.

Pre-cleaning of the substrates is important to remove impurities, such as oxides, from the substrate surface, so that metal films deposited in the deposition chambers are not electrically insulated from the substrate. By performing pre-cleaning in the first and second pre-clean chambers 110, 114 that share the same vacuum environment as the first and second deposition chambers 112, 116, the substrates can be transferred from the cleaning chambers to the deposition chambers without being exposed to atmosphere. This prevents formation of impurities on the substrates during the transfer. In addition, vacuum pump-down cycles are reduced since a vacuum is maintained in the substrate processing system 100 during transfer of the cleaned substrates to the deposition chambers.

In certain embodiments, only one substrate is processed within each pre-clean and deposition chamber at a time. Alternatively, multiple substrates may be processed at one time, such as four to six substrates. In such embodiments, the substrates may be disposed on a rotatable pedestal within the respective chambers. In certain embodiments, the first and second pre-clean chambers 110, 114 are pre-clean etch chambers for etching the substrate surface. However, other types of pre-clean chambers are also contemplated. In certain embodiments, one or both of the pre-clean chambers are replaced with a deposition chamber for performing a reactive sputtering process, such as deposition of silicon nitride, aluminum oxide, or other materials by reactive sputtering. In an Inductively Coupled Plasma (ICP) chamber, a coil at the top of the chamber is energized with an external RF source to create an excitation field in the chamber. Argon gas flows through the chamber from an external gas source. The argon atoms in the chamber are ionized (charged) by the RF energy. The substrate is biased by a DC biasing source coupled to an aluminum pedestal on which the substrate sits. The charged atoms are attracted to the substrate resulting in etching of the substrate surface. Other gases besides argon may be used depending on the desired etch rate and the materials to be etched. An ionization energy level may be relatively low for etching as part of a cleaning process in contrast to a process for etching features in the substrate surface. The lower energy avoids damaging circuit devices and features already formed on the substrate.

In certain embodiments, the first and second deposition chambers 112, 116 are PVD chambers. In such embodiments, the PVD chambers may be configured to deposit copper, titanium, aluminum, gold, nickel, nickel vanadium, silver, and/or tantalum. However, other types of deposition processes and materials are also contemplated. In a PVD chamber, an entire back surface of the substrate is in electrical and thermal contact with the pedestal. Controlling the temperature of the substrate is important during the sputtering process to obtain a predictable and reliable thin film. A coolant system includes an external cooling source that supplies fluid to cooling lines in the pedestal. The cooling source may be replaced or augmented with a heating source to increase the work piece temperature independent of the sputtering process.

In certain embodiments, an RF bias source is electrically coupled to the pedestal to energize the pedestal and thus energize the substrate during the sputtering process. Substrate bias (RF bias) may be used where the substrates/panels have features that require good step coverage, for example. Alternatively, the pedestal may be grounded, floated, or biased with only a DC voltage source.

In operation, the PVD deposition chamber is evacuated and back filled with argon gas. The gas is energized with a DC source to couple an electromagnetic field inside the PVD deposition chamber to excite a sustained high-density plasma near the target surface. The plasma confined near the target surface contains positive ions (such as Ar+) and free electrons. The ions in the plasma strike the target surface and sputter material off the target. The substrate receives the sputtered material to form a deposited layer on the substrate surface. In one example, as much as 20 kilowatts of DC power can be provided on the target enabling the target to deposit approximately 1 micron per minute of material on the substrate.

The PVD deposition chamber uses a magnetron assembly, outside the vacuum, to further control the bombardment of the target by ions formed in the plasma. In certain embodiments, a fixed permanent magnet is located behind the target (serving as a deposition source), so that the plasma is confined to the target area. In other cases, magnets are scanned across the backside of the target to help distribute the magnetic field evenly across the target for more even target erosion. The resulting magnetic field forms a closed-loop annular path acting as an electron trap that reshapes the trajectories of the secondary electrons ejected from the target into a cycloidal path, greatly increasing the probability of ionization of the sputtering gas within the confinement zone. Inert gases, such as argon, are usually employed as the sputtering gas because they tend not to react with the target material or combine with any process gases and because they produce higher sputtering and deposition rates due to their high molecular weight. Positively charged argon ions from the plasma are accelerated toward the negatively biased target and impact the target, resulting in material being sputtered from the target surface.

The chamber wall is typically electrically grounded in processing operations. A bias voltage on the substrate can drive a flux of an electrically charged species (Ar+ and/or atoms sputtered off the target) to the substrate. The flux can modify the properties, such as film density, of the sputtered material deposited on a surface of the substrate.

FIG. 1B is a schematic top isometric view of a portion of the substrate processing system 100 illustrated in FIG. 1A, according to certain embodiments. As shown, the process chamber 130 is configured to receive a panel 110 for processing therein. The process chamber 130 includes an upper chamber 125 and a lower chamber 131 that are configured to receive the panel 110 and form a processing environment therein. In one example, the upper chamber 125 includes a target (not shown) that is used to sputter deposit a layer on a first side 111 of the panel 110 by use of PVD deposition process and the panel is supported on the base 122.

As illustrated in FIG. 1B, a panel 110 is disposed in the transfer chamber 106. An edge of the panel 110 is in contact with an end effector 120A that is coupled to the robot arm 120B of the transfer robot 120. The panel 110 and the end effector of the transfer robot 120 are aligned with a door of the process chamber 130. According to some embodiments, a first side 111 of the panel 110 is facing upwards. The panel 110 can have a thickness in a range from about 0.1 mm to about 4 mm, for example in a range from about 0.2 mm to about 3.2 mm. In the example, the panel 110 is a panel (also referred to herein as a “substrate”).

FIG. 1B further illustrates how the load lock chamber 130 also may include a plurality of sensors 124A, 124B. Each of the sensors 124A, 124B of the plurality of sensors can be optical sensors, proximity sensors, or any combination thereof for analyzing the characteristics of the panel 110 as will be discussed further below.

FIG. 1C illustrates the panel 110 once the transfer robot 120 transfers the panel 110 from the transfer chamber 106 into the process chamber 130. Note that in FIG. 1C, only the transfer chamber 106 and the lower portion 131 of the process chamber 130 are shown for clarity. As shown in FIG. 1C, the transfer robot 120 has moved the panel 110 from the transfer chamber 106 into a lower chamber 131 of the process chamber 130, so that the panel 110 can then be placed on the base 122 positioned below the panel 110, as shown in FIG. 1C. Once the substrate is in the process chamber 130 the transfer robot can release the panel 110 and allow the process chamber 130 to provide support to the panel 110.

Transportation mechanism 120 can transfer panel 110 onto or away from base 122 (FIG. 1D). In this example, as illustrated in FIG. 1D, transportation mechanism 120 includes a robot arm, but can also include other systems, such as conveyer belt systems. Panel 110 may be transferred by transportation mechanism 120 onto base 122 for processing. Base 122 can perform clockwise or counterclockwise rotations by use of a rotational actuator that is coupled to the base to rotate the panel 110 during processing and/or change an orientation of panel 110 relative to the base 122, when the panel 110 is to be placed on or received from the base 122.

In some examples, transportation mechanism 120, base 122 and related supporting components, such as actuators, sensors and other related devices are communicatively coupled with a computing device, such as the system controller 126. In certain embodiments, the computing device comprises one or more processors, one or more storage devices, one or more communication interfaces, and/or other computing components. The computing device can perform calculations and command transportation mechanism 120 and base 122 to perform actions to adjust a position and an orientation of panel 110. In some examples, the computing device is integrated within transportation mechanism 120. Details regarding how the computing device performs calculations can be found below.

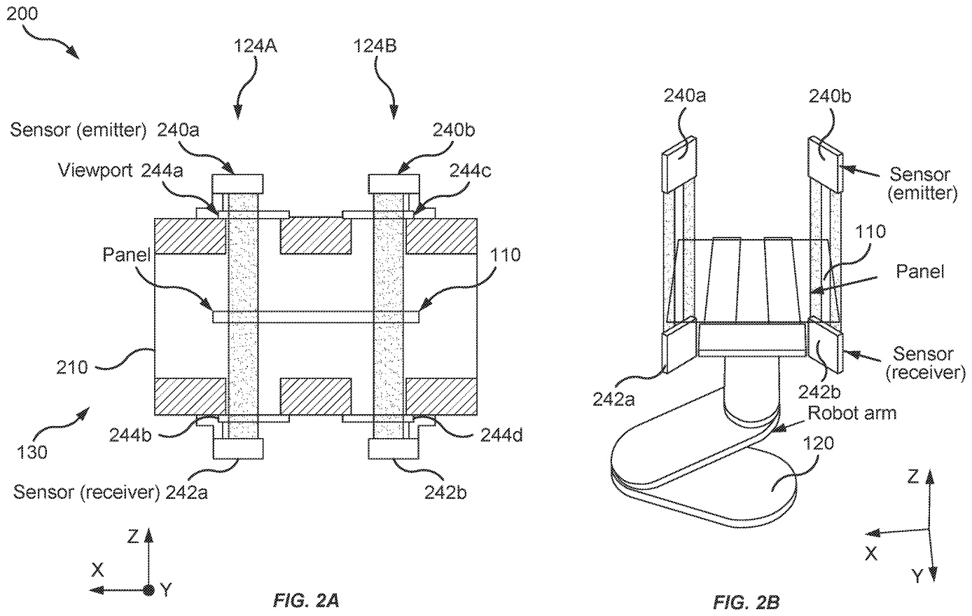

After being placed on base 122, panel 110 may be detected by use of one or more sensors within the sensor array 124, such as sensors 124A and 124B illustrated in FIG. 1B. The one or more sensors in the sensor array 124 may include one or more pairs of light emitters (e.g., laser emitters) and light receptors (e.g., laser receptors). In some examples, additionally or alternatively, sensor array 124 includes one or more cameras (e.g., pinhole cameras, stereo cameras, or thermal cameras) that are positioned above panel 110 so as to view at least a portion of the panel that includes at least one edge. The term “camera” is intended to generally describe a device that is at least able to generate a stream of visual images based on a field-of-view (FOV) of one or more optical components (e.g., lenses), and an image sensor (e.g., CCD, CMOS sensor, etc.). Sensor array 124 can be communicatively coupled with the computing device discussed above. Details regarding sensor array 124 setup can be found below with respect to FIGS. 2A-B.

Sensor data received from the one or more sensors 124A, 124B within the sensor array 124 can be provided to the computing device to calculate a position and an orientation of panel 110 on base 122. The position and the orientation of panel 110 can be compared with a target position and a target orientation of panel 110 by the computing device to calculate a set of corrections needed to reposition panel 110 to the target position and reorient panel 110 to the target orientation. The target position(s) can be stored in memory of the computing device and be derived from prior testing or calibration procedures performed within the substrate processing system 100. The set of corrections can include a rotational correction to adjust the orientation of panel 110 or a translational correction to adjust a translational position of panel 110. The rotational correction can be performed by use of a rotational actuator coupled to the base 122, whereas the translational correction can be performed by controlling the movement of the transportation mechanism 120 relative to the base 122.

In some examples, the computing device (e.g., system controller 126) can use a first machine learning model to help calculate the position or the orientation of panel 110. For example, the first machine learning model can be used to calculate coordinates for a center and some (e.g., at least 2) corners of panel 110. The coordinates for the center of panel 110 can correspond to the position of panel 110, whereas coordinates for the center and the corners of panel 110 can be used to calculate the orientation for panel 110. The first machine learning model can include a convolutional neural network (CNN), a recurrent neural network (RNN), or a residual neural network (ResNet).

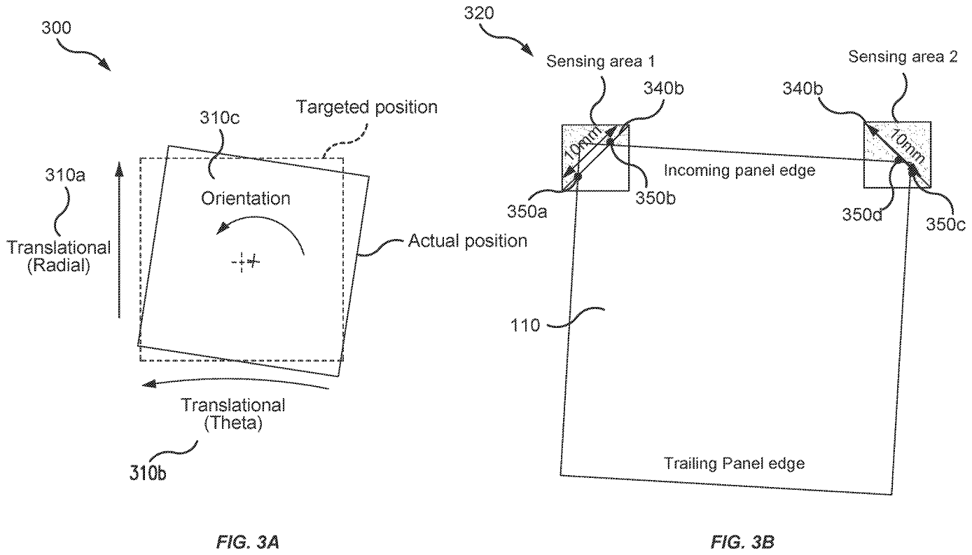

Accordingly, after the position and orientation of panel 110 are calculated, a deviation from the position to the target position (e.g., as a vector) and an angular deviation (e.g., as an angle) can be calculated by the computing device to reflect the corrections to be performed by transportation mechanism 120 and base 122, respectively. For example, the deviation from the position to the target position can be decomposed into the translational correction and the radial correction, whereas the angular deviation can correspond to the rotational correction. Details regarding decomposition of corrections can be found below with respect to FIG. 3A.

In some examples, additionally, the computing device can use a second machine learning model (e.g., a reinforcement learning model) to help command transportation mechanism 120 to perform the translational correction or command base 122 to perform the rotational correction. For example, second machine learning model can include a Deep Q-Network (DQN) or a Proximal Policy Optimization (PPO).

Details regarding the set of corrections can be found below with respect to FIG. 3A and how computing device calculates a position of panel 110 can be found below with respect to FIG. 3B.

### Example Environment for Sensor Array

FIG. 2A illustrates a schematic side view of environment 200, which is a front side view of a portion of the processing chamber 130. FIG. 2B is top isometric view of the the environment 200. FIGS. 2A and 2B both illustrate the environment 200 as viewed from a perspective in which the portion of the processing chamber 130 is being viewed from a position within the transfer chamber 106. As shown, environment 200 includes chamber 210, robot arm 120B, panel 110, two sensors 124A and 124B that include light emitters 240a-b, and light receptors 242a-b, respectively, and viewports 244a-d. Robot arm 120B can be part of transportation mechanism 120, panel 110 can be panel 110, and light emitters 240a-b, light receptors 242a-b, and viewports 244a-d can be part of sensor array 124, as illustrated in FIG. 1D.

As depicted in FIG. 2A, light emitters 240a-b are located at an upper portion of chamber 210 above panel 110 and light receptor 242a-b located at a lower portion of chamber 210 below panel 110. In this example, as illustrated, light emitters 240a-b and light receptors 242a-b are located outside chamber 210. Viewports 244a-d can allow light emitted by light emitters 240a-b to pass through into and out of chamber 210, such that the light may be received by light receptors 242a-b.

In this example, as illustrated, light emitted by light emitter 240a passes through viewports 244a into chamber 210, hits panel 110 (e.g., partly around one corner), and passes from chamber 210 to light receptor 242a through viewport 244b. Similarly, light emitted by light emitter 240b passes through viewports 244c into chamber 210, hits panel 110 (e.g., partly around another corner), and passes from chamber 210 to light receptor 242b through viewport 244d.

In some examples, alternatively, light emitters 240a-b and light receptors 242a-b are located inside chamber 210 (e.g., in protective cases), and viewports 244a-d may be located in chamber 210 as well (e.g., on the protective cases).

In this example, as illustrated, each light emitter is located vertically above a corresponding light receptor. For example, light emitter 240a is located vertically above light receptor 242a, whereas light emitter 240b is located vertically above light receptor 242b. Light emitters 240a-b can emit light in a curtain beam that has an elongated shape directed diagonally at a square region that indicates and/or is used to detect a desired position of a corner of the substrate, and light receptor detects the emitted segments of the diagonal curtain beam. Details regarding the shapes of light beam emitted and received can be found below with respect to FIG. 3B.

As depicted in FIG. 2B, light emitters 240a-b and light receptors 242a-b can be placed to cover two corners on an incoming edge (i.e., leading edge) of a panel 110. Placing sensors such as light emitters 240a-b and light receptors 242a-b away from robot arm 120B would allow robot arm 120B and other transportation mechanisms more room for maneuver when transferring and correcting the position of the panel 110. In another example, alternatively, one pair of light emitter and light receptor can cover a first corner of panel 110 whereas another pair can cover a second corner diagonally across the first corner.

Although shown as including two pairs of sensors, environment 200 can include more pairs of light emitters and light receptors. For example, four pairs of light emitters and light receptors can be used, where each pair covers one respective corner of a square shaped panel 110. This might be useful when each edge of panel 110 has distinct notches indicating a specific target orientation required for panel 110.

In some examples, alternatively or additionally, environment 200 includes other types of sensors, such as cameras, as discussed with respect to FIGS. 1A-1D.

### Example Calculations for Correcting Panel Position and Orientation

FIG. 3A shows an example decomposition 300 of corrections. The set of corrections can include component translational corrections, such as radial correction 310a (e.g., extension of the robot arm 120B of the transportation mechanism 120) and theta correction 310b (e.g., rotation of the transportation mechanism 120 about a vertical central axis) and a rotational correction (e.g., base 122 rotation), such as rotational correction 310c.

The translational correction can be decomposed into radial correction 310a and theta correction 310b. Radial correction 310a and theta correction 310b can be performed by a transportation mechanism, such as transportation mechanism 120 illustrated in FIG. 1A-1D. In this example, radial correction 310a and theta correction 310b are generated based on a translational correction using polar coordinates or spherical coordinates, where the point of reference is the central rotational axis of the transportation mechanism 120 (e.g., along the z-axis as depicted).

As depicted, radial correction 310a changes as the extension of the end effector 120A by the robot arm 120B is altered during operation of a transportation mechanism, and theta correction 310b changes in the direction of the angular operation of the transportation mechanism (e.g., when the transportation mechanism rotates clockwise or counterclockwise) about the central rotational axis.

Similarly, rotational correction 310c can be performed by a rotational base to correct an orientation of the panel, such as base 122 illustrated in FIG. 1D. Rotational correction 310c can indicate an angular change, such as a positive angle indicating a counterclockwise rotation or a negative angle indicating a clockwise rotation.

FIG. 3B, is a bird-eye view of the environment 200 that depicts an example scenario 320 for correction calculation. As depicted, scenario 320 uses two pairs of light emitters and light receptors located to detect two corners on a same incoming edge of panel 110. The curtain beam hits panel 110 with two diagonal line segments, namely line segments 340a-b. In some examples, each of line segments 340 a-b has a length of approximately 10 mm. As depicted, line segments 340 a-b are the diagonal of two square regions that partially cover the two corners of panel 110, respectively. As depicted, each of the square regions is a sensing area observable by a set of sensors, such as sensors 124.

In some embodiments, the curtain beam includes a sensing area that fills the square region that is aligned parallel to the major surface of the panel 110, and thus is configured to detect the overlap between the square region and a corner of a panel 110, as illustrated in FIG. 3B. In some other embodiments, the curtain beam includes a sensing area that extends across a diagonal of the square region and thus is configured to detect the amount a corner of a panel 110 overlaps the length of the curtain beam that extends across the diagonal of the square region.

When the emitted light provided from a light emitter 240a hits a portion of the panel 110, line segment 340a would be partially blocked by panel 110, which forms points 350a-b as the points of intersection between the edge of the panel 110 and the curtain beam. Points 350a-b can be detected by the light receptors due to the detection of a transition between light received from the light emitter and light blocked by the edge of the panel 110. Similarly, line segment 340b intersects panel 110 at points 350c-d. Points 350a-b and points 350c-d can be compared with a set of benchmark points. The benchmark points represent the points of intersection when panel 110 is at the desired target position with the desired target orientation. Accordingly, the directional distance (e.g., a vector) from each point of points 350a-d to its corresponding benchmark point can be used to compute the translational correction and the rotational correction needed to move panel 110 into its target position and target orientation.

### Example Operations for Handling Panel Substrates

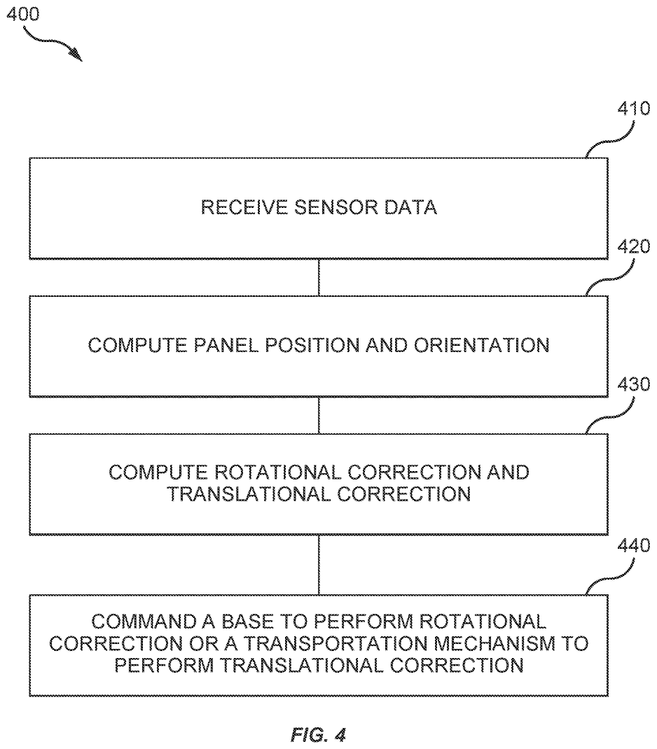

FIG. 4 is a flow diagram of example operations 400 for handling panel substrates. Operations 400 may be performed by a computing device, such as the computing device as discussed with respect to FIGS. 1A-1D. In some embodiments, operations 400 are performed at vacuum.

Operation 400 begins at 410, where a substrate is inserted into a processing chamber 130. During operation 410, sensor data is received by the computing device from a set of sensors indicative of an initial position of a panel substrate over the base 122. In this example, the sensor data can be received from sensor array 124 and the substrate can be panel 110, as illustrated in FIGS. 1A-1D.

In some embodiments, while not intending to be limiting as to the scope of the disclosure provided herein, the set of sensors comprises a light emitter located at an upper portion of a processing chamber above the panel substrate and a light receptor located at a lower portion of the processing chamber below the panel substrate. For example, the light emitter can be one of light emitters 240a-b and the light receptor can be one of light receptors 242a-b, as illustrated in FIG. 2.

In some embodiments, the light emitter is located vertically above the light receptor, wherein the light emitter emits light in a curtain beam directed diagonally at a square that indicates a desired position of a corner of the panel substrate of the panel substrate, and wherein the light receptor detects segments of the diagonal curtain beam. For example, the segments can be one of line segments 340a-b.

In some embodiments, the set of sensors comprises a plurality of cameras at an upper portion of the processing chamber above the panel substrate, as discussed with respect to FIG. 1D.

At 420, a position and an orientation of the panel substrate is computed based on sensor data created by the overlap between the emitted light from a light emitter and a region of the panel 110, or sensor data created by the intrusion of the panel 110 within the field of view of a camera. For example, the position and the orientation of the panel substrate can be computed as discussed with respect to FIG. 1D.

At 430, a rotational correction to adjust an orientation of the panel substrate to be performed by a rotating base 122 or a translational correction to adjust a translational position of the panel substrate to be performed by a transportation mechanism is computed based on the position and the orientation of the panel substrate. For example, the rotational correction and the translational correction can be computed as discussed with respect to FIG. 3B.

In some embodiments, the computing device decomposes the translational correction into a radial correction and a theta correction. For example, such decomposition can be performed as discussed with respect to FIG. 3A. In such embodiments, commanding the transportation mechanism to perform the translational correction comprises commanding the transportation mechanism to perform the radial correction and commanding the transportation mechanism to perform the theta correction.

In some embodiments, the computing of the rotational correction or the translational correction is performed based on a machine learning model. In such embodiments, the machine learning model comprises one or more of a convolutional neural network (CNN), a recurrent neural network (RNN), or a residual neural network (ResNet). For example, a machine learning model can learn from historical or simulated samples, where each sample indicates an input data (e.g., sensor data indicating the positions where the curtain beams hit the corners of the panel substrate) and a label (e.g., the desired output), which may indicate the translational correction or the orientation. As such, the trained machine learning model can compute the translational correction or the orientation to place the panel substrate in the target position and orientation, based on the input data.

At 440, the rotating base is commanded to perform the rotational correction or the transportation mechanism is commanded to perform the translational correction. For example, the rotating base can be base 122 and the transportation mechanism can be transportation mechanism 120, as illustrated in FIGS. 1A-1D. For example, the computing device can first command the transportation mechanism to perform the translational correction on the panel substrate such that the center of mass of the panel substrate aligns with the center of mass of a target position. The computing device can then command the rotating base to perform the rotational correction to correct the orientation of the panel substrate.

In some embodiments, commanding the transportation mechanism to perform the translational correction uses a reinforcement learning model. In such embodiments, the reinforcement learning model comprises a Deep Q-Network (DQN) or a Proximal Policy Optimization (PPO). For example, a reinforcement learning model can learn from historical or simulated episodes (e.g., sequences) of panel substrate movement, where each episode includes a time series of the position and orientation of a panel substrate. The trained reinforcement model can then calculate, at each time step, the desired translational correction or rotational correction to move the panel substrate into the targeted position and orientation.

While the foregoing is directed to embodiments of the present disclosure, other and further embodiments of the disclosure may be devised without departing from the basic scope thereof, and the scope thereof is determined by the claims that follow.

What is claimed is:

1. A semiconductor processing device, comprising:
a processing chamber comprising one or more of:
a rotating base for receiving a panel substrate, wherein the rotating base is capable of adjusting a rotational orientation of the panel substrate disposed thereon about a first axis; and
a set of sensors that are configured detect at least a portion of the panel substrate and at least one edge of the panel substrate when the panel substrate is disposed over the rotating base;
a transportation mechanism capable of transporting the panel substrate in at least one direction that is perpendicular to the first axis; and
a computing device capable of receiving sensor data from the set of sensors and computing, based on the sensor data, a rotational correction to adjust the rotational orientation of the panel substrate to be performed by the rotating base or a translational correction to adjust a translational position of the panel substrate to be performed by the transportation mechanism.

2. The semiconductor processing device of claim 1, wherein the set of sensors comprises a light emitter located at an upper portion of the processing chamber above the panel substrate and a light receptor located at a lower portion of the processing chamber below the panel substrate.

3. The semiconductor processing device of claim 2, wherein the light emitter is located vertically above the light receptor, wherein the light emitter emits light in curtain beam directed diagonally at a square that indicates a desired position of a corner of the panel substrate of the panel substrate, and wherein the light receptor detects segments of the diagonal curtain beam.

4. The semiconductor processing device of claim 1, wherein the set of sensors comprises a plurality of cameras at an upper portion of the processing chamber above the panel substrate.

5. The semiconductor processing device of claim 1, wherein the computing of the rotational correction or the translational correction is performed based on a machine learning model.

6. The semiconductor processing device of claim 5, wherein the machine learning model comprises one or more of a convolutional neural network (CNN), a recurrent neural network (RNN), or a residual neural network (ResNet).

7. The semiconductor processing device of claim 1, wherein the transportation mechanism performs the translational correction using a reinforcement learning model.

8. The semiconductor processing device of claim 7, wherein the reinforcement learning model comprises a Deep Q-Network (DQN) or a Proximal Policy Optimization (PPO).

9. The semiconductor processing device of claim 1, wherein the computing device decomposes translational correction into a radial correction and a theta correction.

10. The semiconductor processing device of claim 9, wherein the translational correction to adjust the translational position of the panel substrate to be performed by the transportation mechanism comprises the radial correction and the theta correction.

11. A method, comprising:
receiving sensor data from a set of sensors indicative of a panel substrate;
computing, based on the sensor data, a position and an orientation of the panel substrate;
computing, based on the position and the orientation of the panel substrate, a rotational correction to adjust an orientation of the panel substrate to be performed by a rotating base or a translational correction to adjust a translational position of the panel substrate to be performed by a transportation mechanism; and
commanding the rotating base to perform the rotational correction or the transportation mechanism to perform the translational correction.

12. The method of claim 11, wherein the set of sensors comprises a light emitter located at an upper portion of a processing chamber above the panel substrate and a light receptor located at a lower portion of the processing chamber below the panel substrate.

13. The method of claim 12, wherein the light emitter is located vertically above the light receptor, wherein the light emitter emits light in curtain beam directed diagonally at a square that indicates a desired position of a corner of the panel substrate of the panel substrate, and wherein the light receptor detects segments of the diagonal curtain beam.

14. The method of claim 11, wherein the set of sensors comprises a plurality of cameras disposed over the panel substrate.

15. The method of claim 11, wherein the computing of the rotational correction or the translational correction is performed based on a machine learning model.

16. The method of claim 15, wherein the machine learning model comprises one or more of a convolutional neural network (CNN), a recurrent neural network (RNN), or a residual neural network (ResNet).

17. The method of claim 11, wherein commanding the transportation mechanism to perform the translational correction uses a reinforcement learning model.

18. The method of claim 17, wherein the reinforcement learning model comprises a Deep Q-Network (DQN) or a Proximal Policy Optimization (PPO).

19. The method of claim 11, wherein a computing device decomposes the translational correction into a radial correction and a theta correction.

20. The method of claim 19, wherein commanding the transportation mechanism to perform the translational correction comprises commanding the transportation mechanism to perform the radial correction and commanding the transportation mechanism to perform the theta correction.
